(19) United States
(12) Patent Application Publication
(10) Pub. No.: US 2024/0414961 A1
(43) Pub. Date: Dec. 12, 2024

(54) DISPLAY APPARATUS

(71) Applicant: Samsung Display Co., Ltd., Yongin-Si (KR)

(72) Inventors: Dongkyun Seo, Yongin-si (KR); Youngjun Kim, Yongin-si (KR); Heekyun Shin, Yongin-si (KR); Junho Sim, Yongin-si (KR); Yangho Jung, Yongin-si (KR)

(21) Appl. No.: 18/675,141

(22) Filed: May 28, 2024

(30) Foreign Application Priority Data
Jun. 12, 2023 (KR) 10-2023-0075069

(51) Int. Cl. H10K 59/127; G02F 1/155

(52) U.S. Cl. CPC H10K 59/1275; G02F 1/155

(57) ABSTRACT

A display apparatus is disclosed that includes a first substrate including a component region and a main display region surrounding at least a portion of the component region, a second substrate disposed on the first substrate and including a component region and a main display region surrounding at least a portion of the component region, a first-1 electrode disposed on one surface of the first substrate, and a second-1 electrode disposed on one surface of the second substrate, wherein each of the first substrate and the second substrate includes an electrochromic material.

### CROSS-REFERENCE TO RELATED APPLICATION

This application is based on and claims priority under 35 U.S.C. § 119 to Korean Patent Application No. 10-2023-0075069, filed on Jun. 12, 2023, in the Korean Intellectual Property Office, the disclosure of which is incorporated by reference herein in its entirety.

### BACKGROUND

### 1. Field

One or more embodiments relate to a display apparatus.

### 2. Description of the Related Art

Display apparatuses visually display data. Display apparatuses may provide an image by using light-emitting diodes. As the applications and structures of display apparatuses have diversified, various designs for embedding a component such as a camera in a display apparatus have been attempted.

### SUMMARY

In order to improve light transmittance in a component region of a display apparatus where components are arranged, attempts have been made to apply a transparent material on a substrate or to use a colored material and to drill a hole overlapping the component region in the substrate. In this case, there are problems of process risks and structural disadvantages. One or more embodiments include a display apparatus with improved light transmittance in a component region. However, the embodiments are only examples, and the scope of the disclosure is not limited thereto.

Additional aspects will be set forth in part in the description which follows and, in part, will be apparent from the description, or may be learned by practice of the presented embodiments of the disclosure.

An embodiment of a display apparatus includes a first substrate including a component region and a main display region surrounding at least a portion of the component region, a second substrate disposed on the first substrate and including a component region and a main display region surrounding at least a portion of the component region, a first-1 electrode disposed on one surface of the first substrate, and a second-1 electrode disposed on one surface of the second substrate, wherein each of the first substrate and the second substrate includes an electrochromic material.

In a plan view, at least one of the first-1 electrode and the second-1 electrode may surround at least a portion of the component region.

At least a portion of the first-1 electrode and at least a portion of the second-1 electrode may overlap each other.

The display apparatus may further include a first-2 electrode disposed on a surface opposite to the one surface of the first substrate, on which the first-1 electrode is disposed.

The display apparatus may further include a second-2 electrode disposed on a surface opposite to the one surface of the second substrate, on which the second-1 electrode is disposed.

Each of the first substrate and the second substrate may include a peripheral region surrounding the main display region, and a portion of the first-1 electrode and a portion of the second-1 electrode may each be arranged in the peripheral region to bypass the main display region.

The second substrate may include an opening arranged in the peripheral region and penetrating the second substrate.

The first-1 electrode and the second-1 electrode may be connected to each other in a portion of the peripheral region.

Transmittance of each of the first substrate and the second substrate may increase when a voltage is applied thereto.

The display apparatus may further include a barrier layer arranged between the first substrate and the second substrate.

An embodiment of a display apparatus includes a substrate including a first substrate, a second substrate, a component region, and a main display region surrounding at least a portion of the component region, a first electrode disposed on one surface of the first substrate, and a second electrode disposed on one surface of the second substrate, wherein transparency of at least one of the first substrate and the second substrate varies according to a voltage applied to the first electrode or the second electrode.

The first electrode may be disposed on a lower surface of the first substrate.

The first electrode or the second electrode may be arranged between the first substrate and the second substrate.

The second electrode may be arranged between the second substrate and an inorganic layer on the substrate.

The first electrode may be inserted into the first substrate, and the second electrode may be inserted into the second substrate.

One surface of the first electrode may be coplanar with the one surface of the first substrate, or one surface of the second electrode may be coplanar with the one surface of the second substrate.

At least a portion of the first electrode may overlap at least a portion of the second electrode.

At least a portion of at least one of the first electrode and the second electrode may overlap the component region.

The display apparatus may further include a barrier layer arranged between the first substrate and the second substrate, and at least one of the first electrode and the second electrode may be arranged in the barrier layer.

The display apparatus may further include a connection line arranged in a peripheral region arranged outside the main display region to bypass the main display region and connected with the first electrode or the second electrode.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is a schematic cross-sectional view of a portion of a display apparatus according to an embodiment;

FIG. 3 is a schematic plan view of a display apparatus according to an embodiment;

FIG. 4 is a cross-sectional view of a portion of a display apparatus according to an embodiment;

FIGS. 5A and 5B are schematic plan views of a portion of a display apparatus according to an embodiment;

FIGS. 6A and 6B are schematic cross-sectional view of a portion of a display apparatus according to an embodiment;

FIGS. 7A and 7B are schematic cross-sectional view of a portion of a display apparatus according to an embodiment;

FIG. 8 is a schematic cross-sectional view of a portion of a display apparatus according to an embodiment;

FIG. 9 is a cross-sectional view of a portion of a display apparatus according to another embodiment;

FIGS. 10A and 10B are schematic plan views of a portion of a display apparatus according to another embodiment;

FIGS. 11A and 11B are schematic cross-sectional view of a portion of a display apparatus according to another embodiment;

FIGS. 12A and 12B are schematic cross-sectional view of a portion of a display apparatus according to another embodiment; and

FIG. 13 is a schematic cross-sectional view of a portion of a display apparatus according to another embodiment.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects of the present description.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.” Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

Hereinafter, embodiments will be described in detail with reference to the accompanying drawings, and in the description with reference to the drawings, the same or corresponding elements are indicated by the same reference numerals and redundant descriptions thereof are omitted.

In the following embodiment, it will be understood that although the terms “first,” “second,” etc. may be used herein to describe various elements, these elements should not be limited by these terms. These terms are only used to distinguish one element from another.

In the following embodiment, the expression of singularity in the present specification includes the expression of plurality unless clearly specified otherwise in context.

In the following embodiment, it will be further understood that the terms “comprises,” “comprising,” “includes,” and “including” used herein specify the presence of stated features or elements, but do not preclude the presence or addition of one or more other features or elements.

In the following embodiment, it will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated for convenience of explanation. In other words, since sizes and thicknesses of elements in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the following embodiment, it will be understood that when a layer, region, or element is connected to another layer, region, or element, the layers, regions or elements may be directly connected, or/and may also be indirectly connected via another layer, region, or element therebetween. For example, in the present specification, when a layer, region, or element is electrically connected to another layer, region, or element, the layers, regions, or elements may not only be directly electrically connected, but may also be indirectly electrically connected via another layer, region, or element therebetween.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

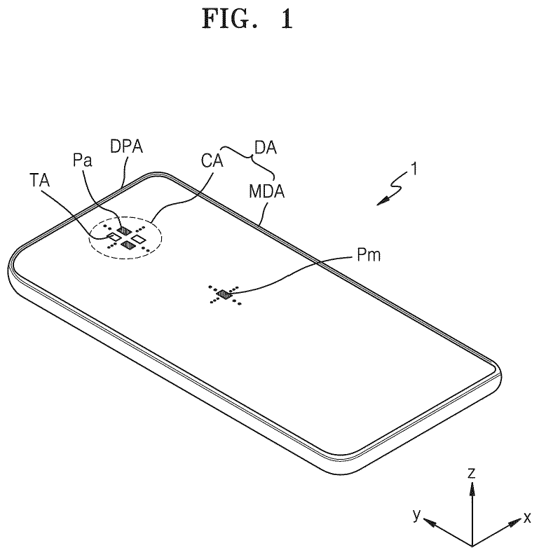

FIG. 1 is a schematic perspective view of a display apparatus according to an embodiment.

Referring to FIG. 1, a display apparatus 1 includes a display region DA and a peripheral region DPA around the display region DA. The display region DA may include a component region CA and a main display region MDA surrounding at least a portion of the component region CA. In other words, each of the component region CA and the main display region MDA may display an image individually or together. The peripheral region DPA may be a kind of non-display region in which display elements are not arranged. The display region DA may be entirely surrounded by the peripheral region DPA.

FIG. 1 shows that one component region CA is arranged in the main display region MDA. In another embodiment, the display apparatus 1 may have two or more component regions CA, and a plurality of component regions CA may have different shapes and sizes. When viewed in a direction substantially perpendicular to an upper surface of the display apparatus 1, the component region CA may have various shapes such as a circle, an ellipse, a polygon such as a quadrangle, a star shape, or a diamond shape. FIG. 1 shows that, when viewed in a direction substantially perpendicular to the upper surface of the display apparatus 1, the component region CA is arranged at an upper center of the main display region MDA (in a y direction) having a substantially quadrangular shape, but the component region CA may be arranged at one side, for example, at an upper right or upper left side, of the main display region MDA having a quadrangular shape.

The display apparatus 1 may provide an image by using a plurality of main sub-pixels Pm arranged in the main display region MDA and a plurality of auxiliary sub-pixels Pa arranged in the component region CA.

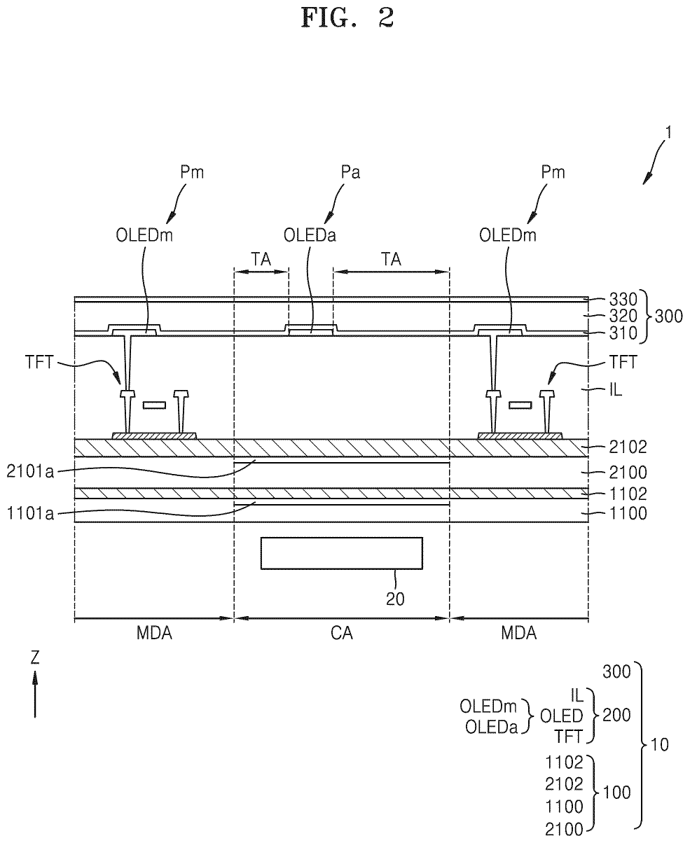

As described below with reference to FIG. 2, in the component region CA, a component 20 which is an electronic clement may be disposed under a substrate 100 to correspond to the component region CA. The component 20 may be a camera which uses infrared rays or visible rays, and may include an image capturing device. Alternatively, the component 20 may be a solar cell, a flash, an illuminance sensor, a proximity sensor, or an iris sensor. Alternatively, the component 20 may have a function of receiving sound. In order to reduce the limitation of the function of the component 20, the component region CA may include a transmission region TA through which light or/and sound output from the component 20 to the outside or traveling from the outside toward the component 20 may pass. In the case of the display apparatus according to an embodiment, when light is transmitted through the component region CA, the light transmittance may be about 10% or more, for example, 40% or more, 25% or more, 50% or more, 85% or more, or 90% or more.

The plurality of auxiliary sub-pixels Pa may be arranged in the component region CA. The plurality of auxiliary sub-pixels Pa may emit light to provide a certain image. An image displayed in the component region CA is an auxiliary image and may have a lower resolution than that of an image displayed in the main display region MDA. In other words, the component region CA includes the transmission region TA through which light or/and sound may be transmitted, and when a sub-pixel is not disposed on the transmission region TA, the number of the auxiliary sub-pixels Pa which may be arranged per unit area may be smaller than the number of the main sub-pixels Pm arranged per unit area in the main display region MDA.

FIG. 2 is a schematic cross-sectional view of a portion of a display apparatus according to an embodiment.

Referring to FIG. 2, the display apparatus 1 may include a display panel 10 including display elements, and the component 20 corresponding to the component region CA.

The display panel 10 may include the substrate 100, a display element layer 200 disposed on the substrate 100, and a thin-film encapsulation layer 300 as a scaling member for sealing the display clement layer 200.

The substrate 100 may have a multilayer structure including a layer including a polymer resin or an inorganic layer. For example, the substrate 100 may include a first substrate 1100, a second substrate 2100 disposed on the first substrate 1100, a first barrier layer 1102 arranged between the first substrate 1100 and the second substrate 2100, and a second barrier layer 2102 disposed on the second substrate 2100.

Each of the first and second barrier layers 1102 and 2102 may include an inorganic insulating material such as silicon oxide (SiOₓ), silicon nitride (SiNₓ), or silicon oxynitride (SiON).

Each of the first and second substrates 1100 and 2100 may include a polymer resin, for example, polyimide.

In some embodiments, each of the first and second substrates 1100 and 2100 may include an electrochromic material that, when exposed to an electric field, undergoes a change. For example, each of the first and second substrates 1100 and 2100 may include electrochromic polyimide that, when exposed to an electric field, increases in transmittance.

In this case, other physical properties of the first and second substrates 1100 and 2100 may be maintained substantially the same as a case where each of the first and second substrates 1100 and 2100 includes a material which does not have electrochromic properties. For example, the transmittance of each of the first and second substrates 1100 and 2100 before application of the electric field may be about 60% to about 65%. The thermal expansion coefficient of each of the first and second substrates 1100 and 2100 may be about 3 ppm/°° C. to about 6 ppm/° C., which may remain the same even after the application of the electric field. The temperature at which a decrease in mass during thermogravimetric analysis of the first and second substrates 1100 and 2100 is observed may be about 530° C. to about 580° C., which may remain the same even after the application of the electric field. The modulus of each of the first and second substrates 1100 and 2100 may be about 9 Gpa to about 12 Gpa, which may remain the same even after the application of the electric field.

After the application of the electric field, electrochromism-related physical properties of the first and second substrates 1100 and 2100 may change. For example, before the application of the electric field, the transmittance of each of the first and second substrates 1100 and 2100 may be about 60% to about 65%, whereas, after the application of the electric field, the transmittance of each of the first and second substrates 1100 and 2100 may be about 80% or more. In this case, a driving voltage of each of the first and second substrates 1100 and 2100 may be about 0.5 V to about 5 V to generate an electrochromic phenomenon. The time for which electrochromism is maintained may be about 0.1 seconds to about 1 second.

By including an electrochromic material in each of the first and second substrates 1100 and 2100, the transmittance of a partial region (for example, the component region CA) may be selectively changed by applying a voltage to a local region. At the same time, stability required as a substrate may be ensured, and the structure of the substrate may not be changed.

The display apparatus 1 may include a first-1 electrode 1101a and a second-1 electrode 2101a as members for applying a voltage to local regions of the first and second substrates 1100 and 2100. In an embodiment, the first-1 electrode 1101a may be disposed on the first substrate 1100, and the second-1 electrode 2101a may be disposed on the second substrate 2100. At least some portions of the first-1 and second-1 electrodes 1101a and 2101a may be respectively disposed on the first and second substrates 1100 and 2100 to overlap the component region CA.

The display element layer 200 may include a circuit layer including a thin-film transistor TFT, an organic light-emitting diode OLED as a display element, and an insulating layer IL arranged therebetween.

The thin-film transistor TFT and a main organic light-emitting diode OLEDm connected with the thin-film transistor TFT may be arranged to implement a main sub-pixel Pm in the main display region MDA of the display panel 10. An auxiliary organic light-emitting diode OLEDa may be arranged in the component region CA to implement an auxiliary sub-pixel Pa. A region of the component region CA, in which the auxiliary sub-pixel Pa is arranged, may be referred to as an auxiliary display region.

The transmission region TA in which the display element is not arranged may be arranged in the component region CA. The transmission region TA may be a region through which light/a signal emitted from the component 20 arranged to correspond to the component region CA or light/a signal incident on the component region CA is transmitted. The auxiliary display region and the transmission region TA may be alternately arranged in the component region CA.

The thin-film encapsulation layer 300 may include at least one inorganic encapsulation layer and at least one organic encapsulation layer. For example, the thin-film encapsulation layer 300 may include a first inorganic encapsulation layer 310, a second inorganic encapsulation layer 330, and an organic encapsulation layer 320 arranged therebetween. Each of the first and second inorganic encapsulation layers 310 and 330 may include at least one inorganic insulating material selected from among aluminum oxide (AlOₓ), titanium oxide (TiOₓ), tantalum oxide (TaOₓ), hafnium oxide (HfOₓ), zinc oxide (ZnOₓ), silicon oxide (SiOₓ), silicon nitride (SiNₓ), and silicon oxynitride (SiON). The organic encapsulation layer 320 may include at least one organic insulating material selected from among polyethylene terephthalate, polyethylene naphthalate, polycarbonate, polyimide, polyethylene sulfonate, polyoxymethylene, polyarylate, and hexamethyldisiloxane.

The area of the component region CA may be greater than the area where the component 20 is arranged. In addition, a plurality of components 20 may be arranged in the component region CA. The plurality of components 20 may have different functions. For example, one of the plurality of components 20 may be a camera, and the other may be an infrared sensor.

Although not shown in FIG. 2, components such as an input sensing member for sensing a touch input, a reflection preventing member including a polarizer and a retarder or a color filter and a black matrix, and a transparent window may be further disposed on the display panel 10.

In the present embodiment, the thin-film encapsulation layer 300 is used as an encapsulation member for sealing the display element layer 200, but the disclosure is not limited thereto. For example, a scaling substrate bonded to the substrate 100 by a sealant or a frit may be used as a member for sealing the display clement layer 200.

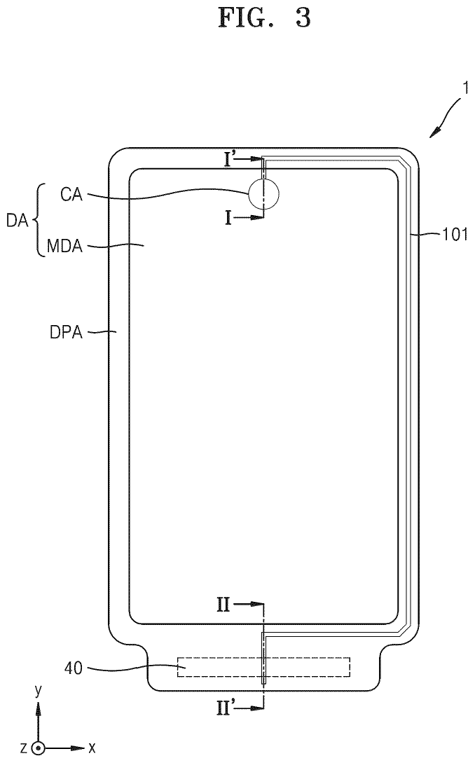

FIG. 3 is a schematic plan view of a display apparatus according to an embodiment.

Referring to FIG. 3, the display apparatus I may include the display region DA and the peripheral region DPA surrounding the display region DA. The display region DA may include the component region CA and the main display region MDA surrounding at least a portion of the component region CA.

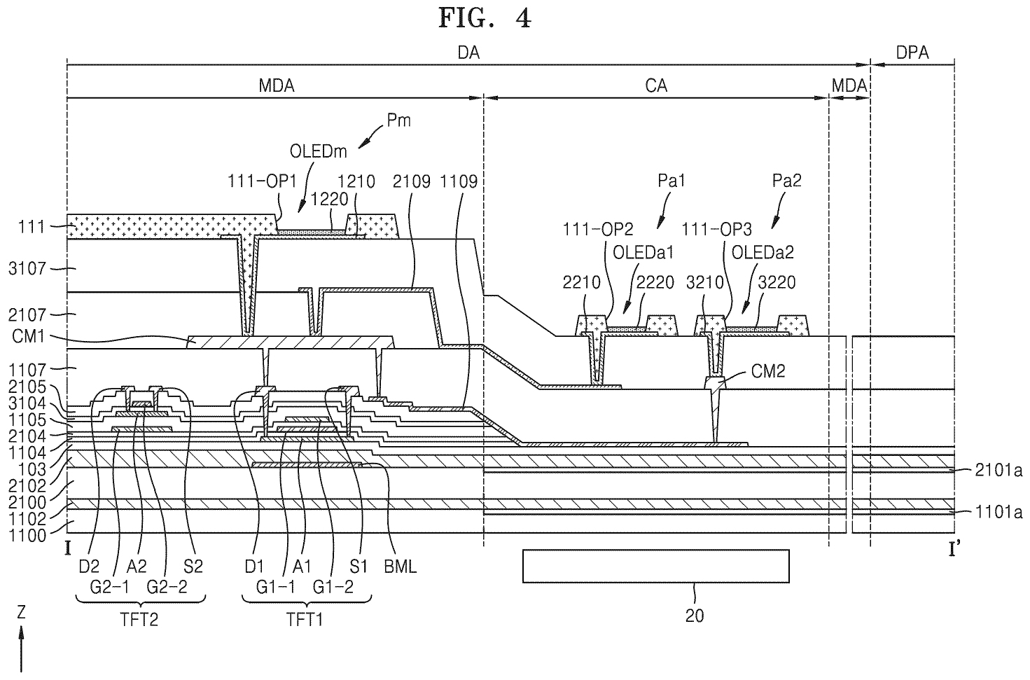

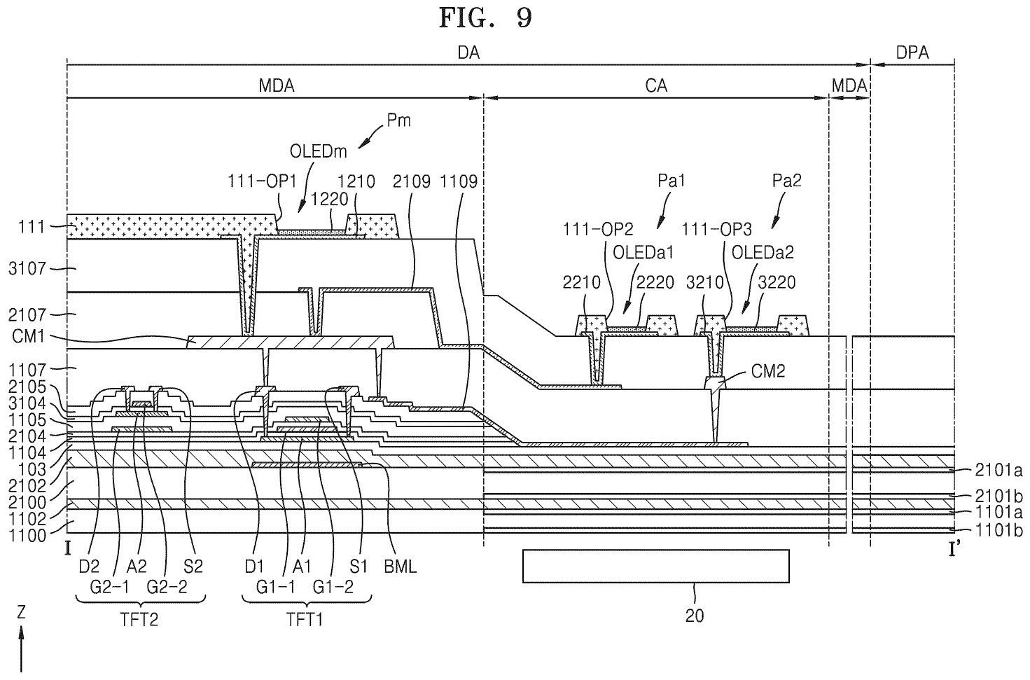

The display apparatus 1 may include an electrode 101 extending from the component region CA to the peripheral region DPA. The electrode 101 may include first-1, first-2, second-1, and second-2 electrodes described below with reference to FIGS. 4 and 9.

The display apparatus 1 may include a terminal portion 40 arranged on one side of the peripheral region DPA. The terminal portion 40 may be connected to a circuit board.

The electrode 101 may extend from the component region CA and may be partially arranged in the peripheral region DPA. For example, the electrode 101 may be arranged in the peripheral region DPA by extending from the component region CA and bypassing the display region DA. In an embodiment, the electrode 101 may extend from the component region CA in a +y direction, may be bent at an upper end of the peripheral region DPA in a ty direction and extend along the peripheral region DPA, and then may be bent at a lower end thereof in the ty direction and connected to the terminal portion 40. In this case, a portion of the electrode 101 may be arranged in a portion of the main display region MDA arranged between the component region CA and the peripheral region DPA.

FIG. 3 shows that the electrode 101 is arranged in a portion of the peripheral region DPA arranged approximately in a +x direction of the display region DA, but the disclosure is not limited thereto. In another embodiment, the electrode 101 may be arranged in a portion of the peripheral region DPA arranged approximately in a −x direction of the display region DA.

FIG. 4 is a cross-sectional view of a portion of a display apparatus according to an embodiment. FIG. 4 is a cross-sectional view of one of various examples of the embodiment shown in FIG. 3 taken along line I-I′.

Referring to FIG. 4, the display apparatus I may include the main display region MDA and the display region DA including the component region CA. The main sub-pixel Pm may be arranged in the main display region MDA, and first and second auxiliary sub-pixels Pa1 and Pa2 may be arranged in the component region CA.

Although not indicated in FIG. 4, a region of the component region CA, in which the first and second auxiliary sub-pixels Pa1 and Pa2 are not arranged, may be the transmission region TA (FIG. 2).

A sub-pixel circuit including first and second thin-film transistors TFT1 and TFT2 and the main organic light-emitting diode OLEDm as a main display element connected with the sub-pixel circuit may be arranged in the main display region MDA. First and second auxiliary organic light-emitting diodes OLEDa1 and OLEDa2 may be arranged as auxiliary display elements in the component region CA.

In the present embodiment, an organic light-emitting diode is employed as a display element, but in another embodiment, an inorganic light-emitting device, a quantum dot light-emitting device, or the like may be employed as a display clement.

The second substrate 2100 may be disposed on the first substrate 1100. The first barrier layer 1102 may be arranged between the first and second substrates 1100 and 2100. The second barrier layer 2102 may be disposed on the second substrate 2100. The first and second barrier layers 1102 and 2102 may prevent penetration of external air into the sub-pixel circuit and the organic light-emitting diode.

FIG. 4 illustrates two substrates and two barrier layers, but the disclosure is not limited thereto, and the number of substrates and the number of barrier layers may vary.

The first-1 electrode 1101a and the second-1 electrode 2101a may be disposed on one surface of each of the first substrate 1100 and the second substrate 2100, respectively. For example, the first-1 electrode 1101a may be disposed on the first substrate 1100, and the second-1 electrode 2101a may be disposed on the second substrate 2100.

FIG. 4 illustrates that the first-1 and second-1 electrodes 1101a and 2101a are disposed on an upper surface of each of the first substrate 1100 and the second substrate 2100, respectively, but the disclosure is not limited thereto. When the first-1 and second-1 electrodes 1101a and 2101a are arranged to correspond to the first and second substrates 1100 and 2100, respectively, there is no limitation on their positions. In an embodiment, the first-1 electrode 1101a may be disposed on the upper surface of the first substrate 1100, and the second-1 electrode 2101a may be disposed on a lower surface of the second substrate 2100 (or between the second substrate 2100 and the first barrier layer 1102). In another embodiment, the first-1 electrode 1101a may be inserted into the first substrate 1100, and the second-1 electrode 2101a may be inserted into the second substrate 2100.

At least a portion of at least one of the first-1 and second-1 electrodes 1101a and 2101a may overlap the component region CA.

The first-1 and second-1 electrodes 1101a and 2101a may overlap at least a portion of the component region CA and overlap a portion of the main display region MDA and may extend to the peripheral region DPA. In an embodiment, a portion of each of the first-1 and second-1 electrodes 1101a and 2101a may be arranged in the component region CA, another portion thereof may be arranged in the main display region MDA arranged between the component region CA and the peripheral region DPA, and another portion thereof may be arranged in the peripheral region DPA.

FIG. 4 illustrates that the first-1 and second-1 electrodes 1101a and 2101a are arranged to overlap the entire component region CA, but the disclosure is not limited thereto. In another embodiment, the first-1 electrode 1101a may be arranged to overlap the entire component region CA, and the second-1 electrode 2101a may be arranged to overlap a portion of the component region CA.

The first-1 and second-1 electrodes 1101a and 2101a may not overlap the main organic light-emitting diode OLEDm.

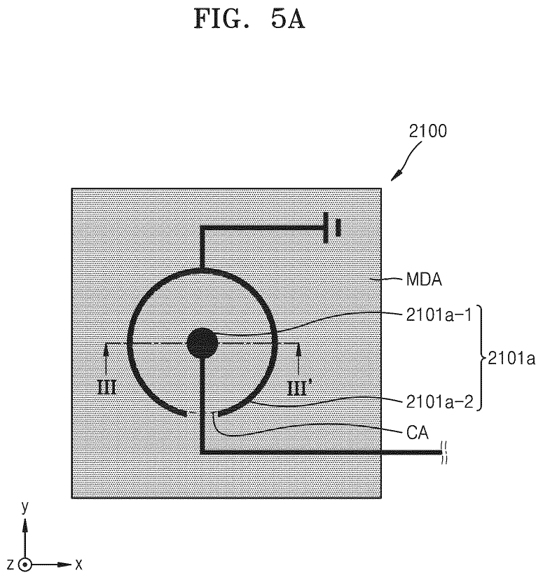

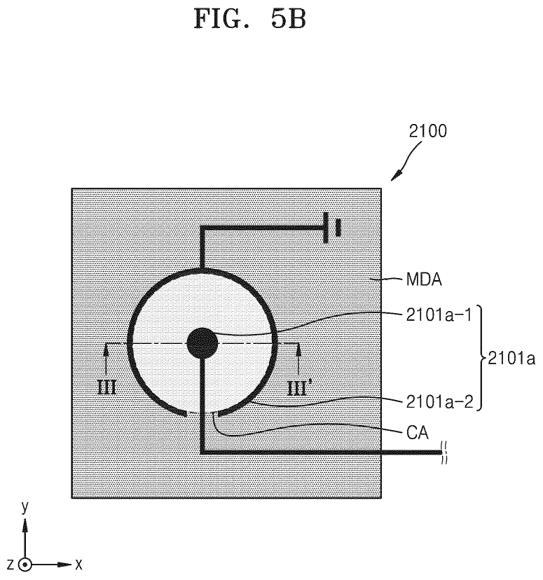

The first-1 and second-1 electrodes 1101a and 2101a may overlap each other. In an embodiment, the first-1 and second-1 electrodes 1101a and 2101a may have a same shape on a plane and may completely overlap each other. This will be described with reference to FIGS. 5A and 5B. The disclosure is not limited thereto, but the first-1 and second-1 electrodes 1101a and 2101a may partially overlap each other. However, in the present specification, for convenience of description, an embodiment of a case where the first-1 and second-1 electrodes 1101a and 2101a completely overlap each other is shown and described.

A lower metal layer BML may be arranged in the second barrier layer 2102. The lower metal layer BML may be arranged to correspond to a lower portion of the first thin-film transistor TFT1. The lower metal layer BML may block external light from reaching the main sub-pixel Pm including the first thin-film transistor TFT1. For example, the lower metal layer BML may prevent light, which is introduced from lower portions of the first and second substrates 1100 and 2100, from reaching the main sub-pixel Pm. In some embodiments, a constant voltage or a signal may be applied to the lower metal layer BML to prevent damage to the sub-pixel circuit due to electrostatic discharge.

The lower metal layer BML may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu). The lower metal layer BML may be a single layer or multilayer of the above-described material.

A buffer layer 103 may be disposed on the second substrate 2100. The buffer layer 103 may be disposed on the first and second substrates 1100 and 2100 to reduce or prevent penetration of foreign substances, moisture, or external air from the lower portions of the first and second substrates 1100 and 2100, and may provide a flat surface on the first and second substrates 1100 and 2100. The buffer layer 103 may include an inorganic material such as an oxide or a nitride, an organic material, or an organic/inorganic composite, and may include a single-layered or multilayer structure of an inorganic material and an organic material. In some embodiments, the buffer layer 103 may have a single-layered or multilayer structure including at least one of silicon oxide (SiOₓ), silicon nitride (SiNₓ), silicon oxynitride (SiON), aluminum oxide (AlOₓ), aluminum nitride (AlNₓ), titanium oxide (TiOₓ), or titanium nitride (TiNₓ).

The first and second thin-film transistors TFT1 and TFT2 may be disposed above the buffer layer 103. The first thin-film transistor TFT1 may include a first activation layer A1, first-1 and first-2 gate electrodes G1-1 and G1-2, a first source electrode S1, and a first drain electrode D1. The second thin-film transistor TFT2 may include a second activation layer A2, second-1 and second-2 gate electrodes G2-1 and G2-2, a second source electrode S2, and a second drain electrode D2. The first thin-film transistor TFT1 may be connected with the main organic light-emitting diode OLEDm to drive the main organic light-emitting diode OLEDm.

In some embodiments, the first thin-film transistor TFT1 may be a driving transistor of the main sub-pixel Pm, and the second thin-film transistor TFT2 may be a switching transistor.

The first activation layer A1 may be disposed on the buffer layer 103 and may include polysilicon. In another embodiment, the first activation layer A1 may include amorphous silicon. The first activation layer A1 may include a channel region, a source region doped with impurities, and a drain region doped with impurities.

The first activation layer A1 may overlap the lower metal layer BML with the buffer layer 103 therebetween. In an embodiment, the width of the first activation layer A1 may be less than the width of the lower metal layer BML, and thus, when viewed in a direction perpendicular to the first activation layer A1, the first activation layer A1 may entirely overlap the lower metal layer BML.

A first gate insulating layer 1104 may be arranged to cover the first activation layer A1. The first gate insulating layer 1104 may include an inorganic insulating material such as silicon oxide (SiOₓ), silicon nitride (SiNₓ), silicon oxynitride (SiON), aluminum oxide (AlOₓ), titanium oxide (TiOₓ), tantalum oxide (TaOₓ), hafnium oxide (HfOₓ), or zinc oxide (ZnOₓ). The first gate insulating layer 1104 may have a single-layered or multilayer structure including the above-described inorganic insulating material.

The first-1 gate electrode G1-1 may be disposed on the first gate insulating layer 1104 to overlap the first activation layer A1. The first-1 gate electrode G1-1 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu), and may have a single-layered or multilayer structure of the above-described material.

A second gate insulating layer 2104 may be arranged to cover the first-1 gate electrode G1-1. The second gate insulating layer 2104 may include an inorganic insulating material such as silicon oxide (SiOₓ), silicon nitride (SiNₓ), silicon oxynitride (SiON), aluminum oxide (AlOₓ), titanium oxide (TiOₓ), tantalum oxide (TaOₓ), hafnium oxide (HfOₓ), or zinc oxide (ZnOₓ). The second gate insulating layer 2104 may have a single-layered or multilayer structure including the above-described inorganic insulating material.

The first-2 gate electrode G1-2 may be disposed on the second gate insulating layer 2104 to overlap the first-1 gate electrode G1-1. The first-2 gate electrode G1-2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu), and may have a single-layered or multilayer structure of the above-described material.

In some embodiments, the first-1 gate electrode G1-1 and the first-2 gate electrode G1-2, which overlap each other with the second gate insulating layer 2104 therebetween, may form a storage capacitor. For example, the first-1 gate electrode G1-1 may be integrally formed with a lower electrode of the storage capacitor, and the first-2 gate electrode G1-2 may be integrally formed with an upper electrode of the storage capacitor. In another embodiment, a lower electrode and upper electrode of the storage capacitor may be formed separately from the first-1 and first-2 gate electrodes G1-1 and G1-2.

The second-1 gate electrode G2-1 may be disposed on the second gate insulating layer 2104 and may be arranged apart from the first-2 gate electrode G1-2. The second-1 gate electrode G2-1 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu), and may have a single-layered or multilayer structure of the above-described material.

A first interlayer insulating layer 1105 may be arranged to cover the first-2 gate electrode G1-2 and the second-1 gate electrode G2-1. The first interlayer insulating layer 1105 may include an inorganic insulating material such as silicon oxide (SiOₓ), silicon nitride (SiNₓ), silicon oxynitride (SiON), aluminum oxide (AlOₓ), titanium oxide (TiOₓ), tantalum oxide (TaOₓ), hafnium oxide (HfOₓ), or zinc oxide (ZnOₓ). The first interlayer insulating layer 1105 may have a single-layered or multilayer structure including the above-described inorganic insulating material.

The second activation layer A2 may be disposed on the first interlayer insulating layer 1105 and may be arranged to overlap the second-1 gate electrode G2-1. The second activation layer A2 may include an oxide of at least one material selected from the group including indium (In), gallium (Ga), tin (Sn), zirconium (Zr), vanadium (V), hafnium (Hf), cadmium (Cd), germanium (Ge), chromium (Cr), titanium (Ti), and zinc (Zn). The second activation layer A2 may include a channel region, a source region doped with impurities, and a drain region doped with impurities.

A third gate insulating layer 3104 may be arranged to cover the second activation layer A2. The third gate insulating layer 3104 may include an inorganic insulating material such as silicon oxide (SiOₓ), silicon nitride (SiNₓ), silicon oxynitride (SiON), aluminum oxide (AlOₓ), titanium oxide (TiOₓ), tantalum oxide (TaOₓ), hafnium oxide (HfOₓ), or zinc oxide (ZnOₓ). The third gate insulating layer 3104 may have a single-layered or multilayer structure including the above-described inorganic insulating material.

The second-2 gate electrode G2-2 may be disposed on the third gate insulating layer 3104 to overlap the second-1 gate electrode G2-1 and the second activation layer A2. The second-2 gate electrode G2-2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu), and may have a single-layered or multilayer structure of the above-described material.

A second interlayer insulating layer 2105 may be arranged to cover the second-2 gate electrode G2-2. The second interlayer insulating layer 2105 may include an inorganic insulating material such as silicon oxide (SiOₓ), silicon nitride (SiNₓ), silicon oxynitride (SiON), aluminum oxide (AlOₓ), titanium oxide (TiOₓ), tantalum oxide (TaOₓ), hafnium oxide (HfOₓ), or zinc oxide (ZnOₓ). The second interlayer insulating layer 2105 may have a single-layered or multilayer structure including the above-described inorganic insulating material.

The first to third gate insulating layers 1104, 2104, and 3104, the first interlayer insulating layer 1105, and the second interlayer insulating layer 2105 may be arranged in the main display region MDA, and may overlap a portion of the component region CA.

The first source electrode S1, the first drain electrode D1, the second source electrode S2, and the second drain electrode D2 may be disposed on the second interlayer insulating layer 2105. The first source electrode S1 and the first drain electrode D1 may be arranged to overlap the first activation layer A1. The second source electrode S2 and the second drain electrode D2 may be arranged to overlap the second activation layer A2.

The first source electrode S1 and the first drain electrode D1 may be connected to the first activation layer A1 via contact holes formed in the first and second interlayer insulting layers 1105 and 2105 and the first to third gate insulating layers 1104, 2104, and 3104.

For example, the first source electrode S1 may be connected to the source region of the first activation layer A1 via contact holes formed in the first and second interlayer insulting layers 1105 and 2105 and the first to third gate insulating layers 1104, 2104, and 3104. The first drain electrode D1 may be connected to the drain region of the first activation layer A1 via contact holes formed in the first and second interlayer insulting layers 1105 and 2105 and the first to third gate insulating layers 1104, 2104, and 3104.

The second source electrode S2 may be connected to the source region of the second activation layer A2 via contact holes formed in the second interlayer insulating layer 2105 and the third gate insulating layer 3104. The second drain electrode D2 may be connected to the rain region of the second activation layer A2 via contact holes formed in the second interlayer insulating layer 2105 and the third gate insulating layer 3104.

A first conductive thin-film layer 1109 may be disposed on the second interlayer insulating layer 2105, in a region in which the first and second thin-film transistors TFT1 and TFT2 are not arranged. The first conductive thin-film layer 1109 may cover portions of the first and second interlayer insulting layers 1105 and 2105 and first to third gate insulating layers 1104, 2104, and 3104. A portion of the first conductive thin-film layer 1109 may be arranged in the main display region MDA, and the first conductive thin-film layer 1109 may extend to the component region CA.

A portion of the first conductive thin-film layer 1109 may overlap the component 20, and may include a material having high transmittance or a transparent material. In an embodiment, the first conductive thin-film layer 1109 may have a single-layered or multilayer structure including a conductive oxide such as indium tin oxide (ITO), indium zinc oxide (IZO), zinc oxide (ZnO), zinc oxide (In₂O₃), indium gallium oxide (IGO), or aluminum zinc oxide (AZO).

A first organic insulating layer 1107 may be arranged to cover the first and second source electrodes S1 and S2, the first and second drain electrodes D1 and D2, and the first conductive thin-film layer 1109. The first organic insulating layer 1107 may be arranged in the main display region MDA, the component region CA, and the peripheral region DPA.

The first organic insulating layer 1107 may include a contact hole overlapping the first drain electrode D1 of the first thin-film transistor TFT1 and a plurality of contact holes overlapping a portion of the first conductive thin-film layer 1109. At least one of the plurality of contact holes overlapping the portion of the first conductive thin-film layer 1109 may be arranged in the main display region MDA, and the other may be arranged in the component region CA.

The first organic insulating layer 1107 may include a general purpose polymer such as benzocyclobutene, polyimide, hexamethyldisiloxane, polymethylmethacrylate, or polystyrene, a polymer derivative having a phenolic group, an acrylic polymer, an imide-based polymer, an aryl ether-based polymer, an amide-based polymer, a fluorine-based polymer, a p-xylene-based polymer, or a vinyl alcohol-based polymer.

First and second contact metals CM1 and CM2 may be disposed on the first organic insulating layer 1107. The first contact metal CM1 may be arranged in the main display region MDA, and the second contact metal CM2 may be arranged in the component region CA. The first contact metal CM1 may be connected with the first drain electrode D1 via a contact hole in the first organic insulating layer 1107, which overlaps the first drain electrode D1, and thus electrically connected with the first thin-film transistor TFT1. The first contact metal CM1 may be connected with a portion of the first conductive thin-film layer 1109 arranged in the main display region MDA via a contact hole in the first organic insulating layer 1107, which overlaps the first conductive thin-film layer 1109. The second contact metal CM2 may be connected with a portion of the first conductive thin-film layer 1109 arranged in the component region CA via a contact hole in the first organic insulating layer 1107, which overlaps the first conductive thin-film layer 1109.

Each of the first and second contact metals CM1 and CM2 may include aluminum (Al), copper (Cu), or titanium (Ti), and may be formed as a single layer or a multilayer, each including the above-described material.

A second organic insulating layer 2107 may be disposed on the first organic insulating layer 1107. The second organic insulating layer 2107 may be arranged in the main display region MDA. The second organic insulating layer 2107 may include a plurality of contact holes overlapping the first contact metal CM1.

The second organic insulating layer 2107 may include a general purpose polymer such as benzocyclobutene, polyimide, hexamethyldisiloxane, polymethylmethacrylate, or polystyrene, a polymer derivative having a phenolic group, an acrylic polymer, an imide-based polymer, an aryl ether-based polymer, an amide-based polymer, a fluorine-based polymer, a p-xylene-based polymer, or a vinyl alcohol-based polymer.

A second conductive thin-film layer 2109 may be disposed on the first and second organic insulating layers 1107 and 2107. A portion of the second conductive thin-film layer 2109 may be arranged in the main display region MDA, and the second conductive thin-film layer 2109 may extend to the component region CA.

A portion of the second conductive thin-film layer 2109 may be connected with the first contact metal CM1 via a contact hole in the second organic insulating layer 2107, which overlaps the first contact metal CM1.

A portion of the second conductive thin-film layer 2109 may overlap the component 20, and may include a material having high transmittance or a transparent material. In an embodiment, the second conductive thin-film layer 2109 may have a single-layered or multilayer structure including a conductive oxide such as indium tin oxide (ITO), indium zinc oxide (IZO), zinc oxide (ZnO), zinc oxide (In₂O₃), indium gallium oxide (IGO), or aluminum zinc oxide (AZO).

A third organic insulating layer 3107 may be disposed on the second organic insulating layer 2107. The third organic insulating layer 3107 may be arranged in the main display region MDA, the component region CA, and the peripheral region DPA.

The third organic insulating layer 3107 may include a contact hole overlapping the first contact metal CM1, a contact hole overlapping the second conductive thin-film layer 2109 in the component region CA, and a contact hole overlapping the second contact metal CM2.

A portion of the first contact metal CM1 may be exposed via a contact hole through the second and third organic insulating layers 2107 and 3107, which overlaps the first contact metal CM1.

The third organic insulating layer 3107 may include a general purpose polymer such as benzocyclobutene, polyimide, hexamethyldisiloxane, polymethylmethacrylate, or polystyrene, a polymer derivative having a phenolic group, an acrylic polymer, an imide-based polymer, an aryl ether-based polymer, an amide-based polymer, a fluorine-based polymer, a p-xylene-based polymer, or a vinyl alcohol-based polymer.

A main sub-pixel electrode 1210 may be disposed on the third organic insulating layer 3107 of the main display region MDA. A first auxiliary sub-pixel electrode 2210 and a second auxiliary sub-pixel electrode 3210 may be disposed on the third organic insulating layer 3107 of the component region CA.

The main sub-pixel electrode 1210 may be connected to the first contact metal CM1 via a contact hole through the second and third organic insulating layers 2107 and 3107, which overlaps the first contact metal CM1. Therefore, the main sub-pixel electrode 1210 may be electrically connected to the first thin-film transistor TFT1 via the first contact metal CM1 and the first drain electrode D1.

The first auxiliary sub-pixel electrode 2210 may be connected to the second conductive thin-film layer 2109 via a contact hole in the third organic insulating layer 3107, which overlaps the second conductive thin-film layer 2109. Therefore, the first auxiliary sub-pixel electrode 2210 may be electrically connected to the first thin-film transistor TFT1 via the second conductive thin-film layer 2109, the first contact metal CM1, and the first drain electrode D1.

The second auxiliary sub-pixel electrode 3210 may be connected to the second contact metal CM2 via a contact hole in the third organic insulating layer 3107, which overlaps the second contact metal CM2. Therefore, the second auxiliary sub-pixel electrode 3210 may be electrically connected to the first thin-film transistor TFT1 via the second contact metal CM2, the first conductive thin-film layer 1109, the first contact metal CM1, and the first drain electrode D1.

Each of the main sub-pixel electrode 1210 and the first and second auxiliary sub-pixel electrodes 2210 and 3210 may include a conductive oxide such as indium tin oxide (ITO), indium zinc oxide (IZO), zinc oxide (ZnO), zinc oxide (In₂O₃), indium gallium oxide (IGO), or aluminum zinc oxide (AZO). Each of the main sub-pixel electrode 1210 and the first and second auxiliary sub-pixel electrodes 2210 and 3210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. For example, each of the main sub-pixel electrode 1210 and the first and second auxiliary sub-pixel electrodes 2210 and 3210 may have a structure in which films formed of ITO, IZO, ZnO, or In₂O₃ are formed on one surface or both surfaces of the above-described reflective film. In an embodiment, each of the main sub-pixel electrode 1210 and the first and second auxiliary sub-pixel electrodes 2210 and 3210 may have a structure of a stack of ITO/Ag/ITO.

A subpixel-defining film 111 may be disposed on the third organic insulating layer 3107. The subpixel-defining film 111 may cover an edge region (or edge) of each of the main sub-pixel electrode 1210 and the first and second auxiliary sub-pixel electrodes 2210 and 3210.

In other words, the subpixel-defining film 111 may include an opening which exposes a central portion of each of the main sub-pixel electrode 1210 and the first and second auxiliary sub-pixel electrodes 2210 and 3210.

For example, the subpixel-defining film 111 may include a first opening 111-OP1 which exposes a central portion of the main sub-pixel electrode 1210. The subpixel-defining film 111 may include a second opening 111-OP2 which exposes a central portion of the first auxiliary sub-pixel electrode 2210. The subpixel-defining film 111 may include a third opening 111-OP3 which exposes a central portion of the second auxiliary sub-pixel electrode 3210.

The size and shape of an emission region of the main organic light-emitting diode OLEDm, that is, the main sub-pixel Pm, may be defined by the first opening 111-OP1 of the subpixel-defining film 111. The size and shape of an emission region of the first auxiliary organic light-emitting diode OLEDa1, that is, the first auxiliary sub-pixel Pa1, may be defined by the second opening 111-OP2 of the subpixel-defining film 111. The size and shape of an emission region of the second auxiliary organic light-emitting diode OLEDa2, that is, the second auxiliary sub-pixel Pa2, may be defined by the third opening 111-OP3 of the subpixel-defining film 111.

A main intermediate layer 1220, a first auxiliary intermediate layer 2220, and a second auxiliary intermediate layer 3220 may be respectively arranged in the first to third openings 111-OP1, 111-OP2, and 111-OP3 of the subpixel-defining film 111. For example, the main intermediate layer 1220 may be arranged in the first opening 111-OP1 and disposed on the main sub-pixel electrode 1210. The first auxiliary intermediate layer 2220 may be arranged in the second opening 111-OP2 and disposed on the first auxiliary sub-pixel electrode 2210. The second auxiliary intermediate layer 3220 may be arranged in the third opening 111-OP3 and disposed on the second auxiliary sub-pixel electrode 3210.

Each of the main intermediate layer 1220 and the first and second auxiliary intermediate layers 2220 and 3220 may include an emission layer (EML) including a low-molecular-weight or polymer material. Each of the main intermediate layer 1220 and the first and second auxiliary intermediate layers 2220 and 3220 may have a structure in which a hole injection layer (HIL), a hole transport layer (HTL), an EML, an electron transport layer (ETL), or an electron injection layer (EIL) are stacked in a single or complex structure.

Although not shown in FIG. 4, an opposite electrode may be arranged to cover the main intermediate layer 1220 and the first and second auxiliary intermediate layers 2220 and 3220. In addition, the thin-film encapsulation layer 300 (FIG. 2) may be disposed on the opposite electrode.

FIG. 4 illustrates that a portion of each of the main sub-pixel electrode 1210, the first and second auxiliary sub-pixel electrodes 2210 and 3210, and the second conductive thin-film layer 2109 is arranged in a contact hole, but the disclosure is not limited thereto. In another embodiment, each of the main sub-pixel electrode 1210, the first and second auxiliary sub-pixel electrodes 2210 and 3210, and the second conductive thin-film layer 2109 may be electrically connected with a lower layer (for example, the first contact metal CM1, the second contact metal CM2, and the second conductive thin-film layer 2109) via a separate contact metal arranged in a contact hole.

FIGS. 5A and 5B are schematic plan views of a portion of a display apparatus according to an embodiment.

FIGS. 5A and 5B are schematic plan views of a portion of a display apparatus according to the embodiment shown in FIG. 4.

Referring to FIG. 5A, the second substrate 2100 may include the component region CA and the main display region MDA surrounding at least a portion of the component region CA.

The second-1 electrode 2101a may be arranged to substantially surround the component region CA. For example, the second-1 electrode 2101a may include a second portion 2101a-2 having a substantially circular shape with one side open and substantially surrounding the component region CA. The second-1 electrode 2101a may include a first portion 2101a-1 extending from a central portion of the component region CA to the main display region MDA through the one open side of the second portion 2101a-2.

Either the first portion 2101a-1 or the second portion 2101a-2 of the second-1 electrode 2101a may be grounded. FIG. 5A illustrates that the second portion 2101a-2 is grounded, but in another embodiment, the first portion 2101a-1 may be grounded.

Because the second substrate 2100 may include an insulating material, the first portion 2101a-1 or the second portion 2101a-2 may extend to an arbitrary region within the second substrate 2100 and be grounded.

FIG. 5A illustrates that the component region CA has a circular shape and the second portion 2101a-2 of the second-1 electrode 2101a has a substantially circular shape surrounding the component region CA, but the disclosure is not limited thereto. In another embodiment, the shape of the component region CA may be variously transformed into a polygon, a star shape, or a diamond shape, and the second portion 2101a-2 may surround a portion of the component region CA.

Referring to FIG. 5B, a voltage may be applied to a non-grounded portion (for example, the first portion 2101a-1) of the second-1 electrode 2101a. In this case, a potential difference may occur between the first portion 2101a-1 and the second portion 2101a-2, and a portion of the second substrate 2100, which is arranged therebetween, may be exposed to an electric field.

Because the second substrate 2100 may include an electrochromic material, the transmittance of the second substrate 2100 may change when the second substrate 2100 is exposed to an electric field. For example, when the second substrate 2100 is exposed to an electric field, the transmittance of the second substrate 2100 may increase. An electric field may be formed in a region (or the component region CA) between the first portion 2101a-1 and the second portion 2101a-2 of the second-1 electrode 2101a due to a potential difference therebetween. A portion of the second substrate 2100, which corresponds to the component region CA, may be exposed to an electric field, and thus, the transmittance of the second substrate 2100 may increase.

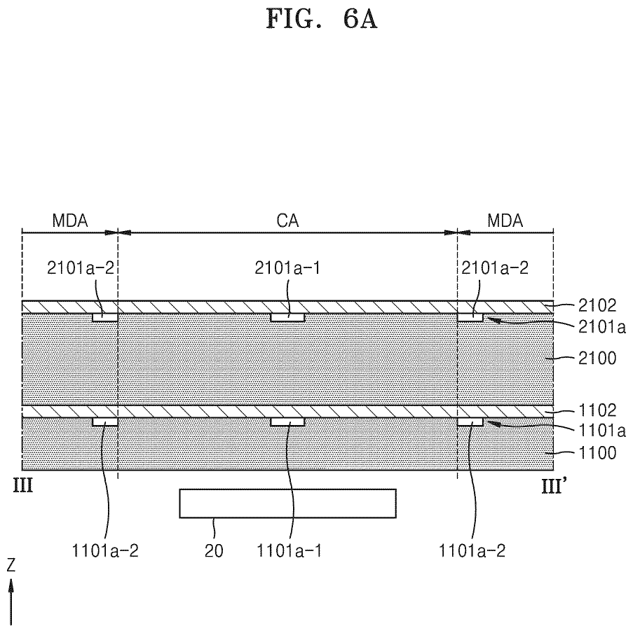

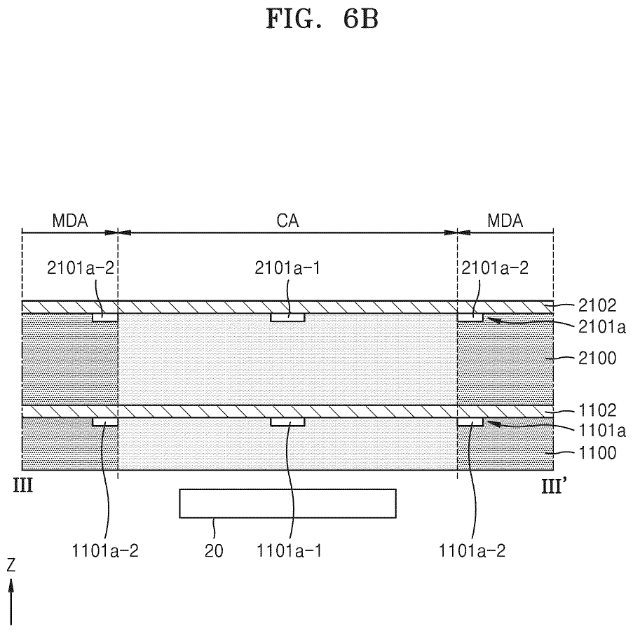

Although not shown in FIGS. 5A and 5B, the first substrate 1100 (FIG. 6A) and the first-1 electrode 1101a (FIG. 6A) may be arranged in a −z direction of the second substrate 2100. Like the second-1 electrode 2101a, the first-1 electrode 1101a (FIG. 6A) may include first and second portions 1101a-1 and 1101a-2, respectively (FIG. 6A).

The first-1 electrode 1101a (FIG. 6A) may have a shape same as that of the second-1 electrode 2101a. Therefore, in a plan view, the first-1 electrode 1101a (FIG. 6A) may be covered by the second-1 electrode 2101a and thus may not be visible. The disclosure is not limited thereto, and in another embodiment, the first-1 electrode 1101a (FIG. 6A) and the second-1 electrode 2101a may partially overlap each other.

A process of applying a voltage to the first-1 electrode 1101a (FIG. 6A) to form an electric field and changing the transmittance of the first substrate 1100 (FIG. 6A) may be similar to the relationship between the second-1 electrode 2101a and the second substrate 2100.

FIGS. 6A and 6B are schematic cross-sectional view of a portion of a display apparatus according to an embodiment.

FIG. 6A may be a cross-sectional view of one of various examples of the embodiment shown in FIG. 5A taken along line III-III′.

FIG. 6B may be a cross-sectional view of one of various examples of the embodiment shown in FIG. 5B taken along line III-III′.

Referring to FIG. 6A, the second-1 electrode 2101a may include the first portion 2101a-1 and the second portion 2101a-2. The first-1 electrode 1101a may include the first portion 1101a-1 and the second portion 1101a-2.

Planar shapes of the second-1 electrode 2101a and the first-1 electrode 1101a may be similar to those described with reference to FIGS. 5A and 5B.

For example, the second portion 2101a-2 of the second-1 electrode 2101a and the second portion 1101a-2 of the first-1 electrode 1101a may be respectively grounded to the second substrate 2100 and the first substrate 1100.

FIG. 6A illustrates that the first-1 and second-1 electrodes 1101a and 2101a, respectively, completely overlap each other, but the disclosure is not limited thereto. In another embodiment, the first-1 and second-1 electrodes 1101a and 2101a may partially overlap each other.

The first-1 electrode 1101a may be arranged in a groove formed in one surface of the first substrate 1100. In other words, an upper surface (or lower surface) of the first-1 electrode 1101a may be coplanar with an upper surface (or lower surface) of the first substrate 1100.

FIG. 6A illustrates that the first-1 electrode 1101a is disposed on the upper surface of the first substrate 1100, but the disclosure is not limited thereto. In another embodiment, the first-1 electrode 1101a may be disposed on the lower surface of the first substrate 1100. In another embodiment, the first-1 electrode 1101a may be inserted into the first substrate 1100.

The second-1 electrode 2101a may be arranged in a groove formed on one surface of the second substrate 2100. In other words, an upper surface (or lower surface) of the second-1 electrode 2101a may be coplanar with an upper surface (or lower surface) of the second substrate 2100.

FIG. 6A illustrates that the second-1 electrode 2101a is disposed on the upper surface of the second substrate 2100, but the disclosure is not limited thereto. In another embodiment, the second-1 electrode 2101a may be disposed on the lower surface of the second substrate 2100. In another embodiment, the second-1 electrode 2101a may be inserted into the second substrate 2100.

Referring to FIG. 6B, a voltage may be applied to a non-grounded portion (for example, the first portion 1101a-1) of the first-1 electrode 1101a. In this case, a potential difference may occur between the first portion 1101a-1 and the second portion 1101a-2, and a portion of the first substrate 1100, which is arranged therebetween, may be exposed to an electric field.

Because the first substrate 1100 may include an electrochromic material, the transmittance of the first substrate 1100 may change when the first substrate 1100 is exposed to an electric field. For example, when the first substrate 1100 is exposed to an electric field, the transmittance of the first substrate 1100 may increase. An electric field may be formed in the component region CA due to a potential difference between the first portion 1101a-1 and the second portion 1101a-2 of the first-1 electrode 1101a. A portion of the first substrate 1100, which corresponds to the component region CA, may be exposed to an electric field, and thus, the transmittance of the first substrate 1100 may increase.

A voltage may be applied to a non-grounded portion (for example, the first portion 2101a-1) of the second-1 electrode 2101a. In this case, a potential difference may occur between the first portion 2101a-1 and the second portion 2101a-2, and a portion of the second substrate 2100, which is arranged therebetween, may be exposed to an electric field.

Because the second substrate 2100 may include an electrochromic material, the transmittance of the second substrate 2100 may change when the second substrate 2100 is exposed to an electric field. For example, when the second substrate 2100 is exposed to an electric field, the transmittance of the second substrate 2100 may increase. An electric field may be formed in the component region CA due to a potential difference between the first portion 2101a-1 and the second portion 2101a-2 of the second-1 electrode 2101a. A portion of the second substrate 2100, which corresponds to the component region CA, may be exposed to an electric field, and thus, the transmittance of the second substrate 2100 may increase.

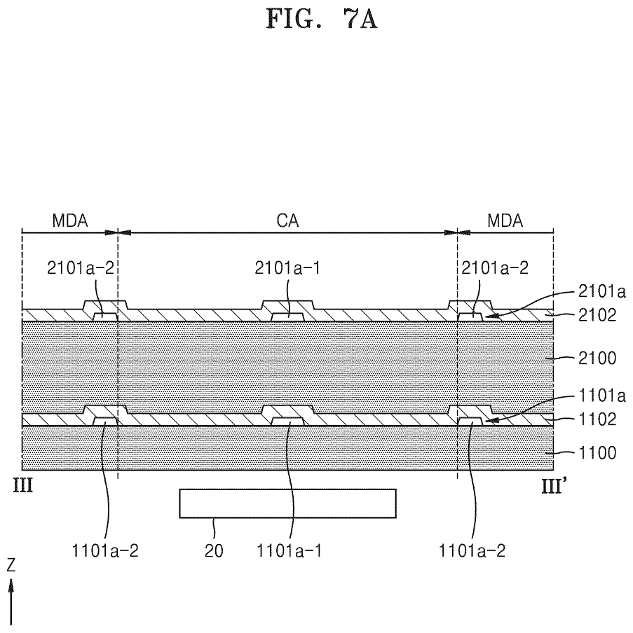

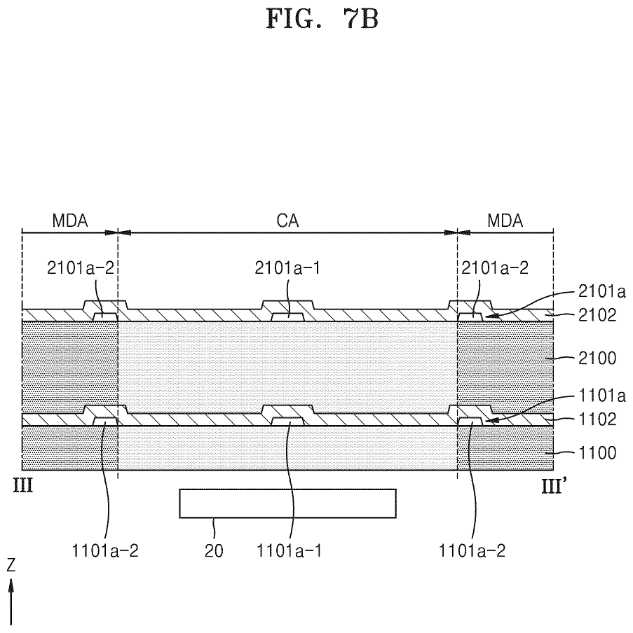

FIGS. 7A and 7B are schematic cross-sectional view of a portion of a display apparatus according to another embodiment.

FIG. 7A may be a cross-sectional view of one of various examples of the embodiment shown in FIG. 5A taken along line III-III′.

FIG. 7B may be a cross-sectional view of one of various examples of the embodiment shown in FIG. 5B taken along line III-III′.

Referring to FIG. 7A, the first-1 electrode 1101a may be disposed on the first substrate 1100. In this case, the first-1 electrode 1101a may be patterned on the first substrate 1100. In other words, a lower surface of the first-1 electrode 1101a may be coplanar with an upper surface of the first substrate 1100.

The second-1 electrode 2101a may be disposed on the second substrate 2100. In this case, the second-1 electrode 2101a may be patterned on the second substrate 2100. In other words, a lower surface of the second-1 electrode 2101a may be coplanar with an upper surface of the second substrate 2100.

In addition, features related to the embodiments shown in FIGS. 7A and 7B are the same as those described with reference to FIGS. 6A and 6B.

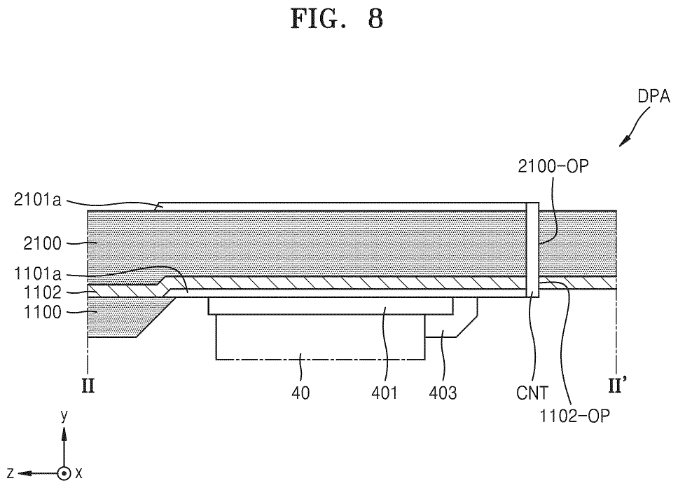

FIG. 8 is a schematic cross-sectional view of a portion of a display apparatus according to an embodiment.

FIG. 8 is a cross-sectional view of one of various examples of the embodiment shown in FIG. 3 taken along line II-II′.

Referring to FIG. 8, the second substrate 2100 may include an opening 2100-OP arranged in the peripheral region DPA and penetrating the second substrate 2100. The first barrier layer 1102 may include an opening 1102-OP arranged in the peripheral region DPA and penetrating the first barrier layer 1102. The opening 2100-OP of the second substrate 2100 and the opening 1102-OP of the first barrier layer 1102 may overlap each other.

In some embodiments, the first barrier layer 1102 may be omitted.

The second-1 electrode 2101a may be disposed on the second substrate 2100. The first-1 electrode 1101a may be disposed below the first barrier layer 1102.

A connection line CNT may be arranged in the opening 2100-OP of the second substrate 2100 and the opening 1102-OP of the first barrier layer 1102. The connection line CNT may be connected to the second-1 electrode 2101a and the first-1 electrode 1101a. In some embodiments, the connection line CNT may be a portion of the second-1 electrode 2101a or the first-1 electrode 1101a extending from the second-1 electrode 2101a or the first-1 electrode 1101a, respectively.

The second-1 electrode 2101a and the first-1 electrode 1101a may be electrically connected to each other via the connection line CNT. A same voltage may be applied to the second-1 electrode 2101a and the first-1 electrode 1101a.

A portion of the second-1 electrode 2101a, to which a voltage is applied, may be the first portion 2101a-1 (FIG. 5B) of the second-1 electrode 2101a. Therefore, according to the embodiment shown in FIG. 8, in the second-1 electrode 2101a, the second portion 2101a-2 (FIG. 5B) may be grounded, and a voltage may be applied to the first portion 2101a-1 (FIG. 5B). This may be similarly applied to the first-1 electrode 1101a.

The terminal portion 40 may be arranged to be adjacent to the first-1 electrode 1101a.

A bump layer 401 may be arranged between the terminal portion 40 and the first-1 electrode 1101a. The bump layer 401 may include a plurality of bumps including a conductive material (for example, metal). For example, the bump layer 401 may include a plurality of bumps including copper (Cu), nickel (Ni), tin (Sn), or gold (Au) or including an alloy including at least one of copper (Cu), nickel (Ni), tin (Sn), and gold (Au).

Electrical signals generated from the terminal portion 40 may be transferred to the display panel 10 (FIG. 2) via the bump layer 401. Although not shown in FIG. 8, the display apparatus may further include a separate line which is contact with the bump layer 401 and connected to the display panel.

In some embodiments, bumps of the bump layer 401 may be formed directly on the terminal portion 40, and thus, the bump layer 401 may be a portion of the terminal portion 40.

A conductive ink layer 403 may protrude from a side surface of the terminal portion 40 and may be connected to the bottom of the first-1 electrode 1101a. The conductive ink layer 403 may include a conductive material (for example, metal).

The conductive ink layer 403 may electrically connect the terminal portion 40 with the first-1 electrode 1101a. An electrical signal generated from the terminal portion 40 may be transferred to the first-1 electrode 1101a, the connection line CNT, and the second-1 electrode 2101a via the conductive ink layer 403. In other words, the first-1 electrode 1101a and the second-1 electrode 2101a may receive a voltage from the terminal portion 40 via the conductive ink layer 403.

FIG. 8 illustrates that the terminal portion 40, the bump layer 401, and the conductive ink layer 403 are disposed under the first-1 electrode 1101a, but the disclosure is not limited thereto. In another embodiment, the terminal portion 40, the bump layer 401, and the conductive ink layer 403 may be disposed on the second-1 electrode 2101a.

FIG. 9 is a cross-sectional view of a portion of a display apparatus according to another embodiment. FIG. 9 is a cross-sectional view of one of various examples of the embodiment shown in FIG. 3 taken along line I-I′.

Other features except for some of the features of the embodiment shown in FIG. 9 are previously described with reference to FIG. 4 and thus omitted, and hereinafter, differences are mainly described.

A first-2 electrode 1101b may be disposed on a lower surface of the first substrate 1100. In other words, the first-2 electrode 1101b may be disposed on one surface of the first substrate 1100, which faces the component 20.

A second-2 electrode 2101b may be arranged between the second substrate 2100 and the first barrier layer 1102. In other words, the second-2 electrode 2101b may be disposed on one surface of the second substrate 2100, which faces the first barrier layer 1102.

At least a portion of each of the first-2 and second-2 electrodes 1101b and 2101b may overlap the component 20. For example, at least a portion of the first-2 electrode 1101b may overlap the first-1 electrode 1101a. At least a portion of the second-2 electrode 2101b may overlap the second-1 electrode 2101a.

At least a portion of each of the first-2 and second-2 electrodes 1101b and 2101b may be arranged in the component region CA, may overlap a portion of the main display region MDA, and may extend to the peripheral region DPA. In an embodiment, a portion of each of the first-2 and second-2 electrodes 1101b and 2101b may be arranged in the component region CA, another portion thereof may be arranged in the main display region MDA arranged between the component region CA and the peripheral region DPA, and another portion thereof may be arranged in the peripheral region DPA.

FIG. 9 illustrates that the first-2 and second-2 electrodes 1101b and 2101b are arranged to overlap the entire component region CA, but the disclosure is not limited thereto. In another embodiment, the first-2 electrode 1101b may be arranged to overlap the entire component region CA, and the second-2 electrode 2101b may be arranged to overlap a portion of the component region CA.

The first-2 and second-2 electrodes 1101b and 2101b may not overlap the main organic light-emitting diode OLEDm.

FIG. 9 illustrates all of the first-1 to second-2 electrodes 1101a, 1101b, 2101a, and 2101b, but the disclosure is not limited thereto, and some of the first-1 to second-2 electrodes 1101a, 1101b, 2101a, and 2101b may be omitted. In another embodiment, the display apparatus 1 may include the first-1 electrode 1101a, the second-1 electrode 2101a, and the second-2 electrode 2101b. Alternatively, the display apparatus 1 may include the first-1 electrode 1101a, the first-2 electrode 1101b, and the second-1 electrode 2101a.

The first-1 and first-2 electrodes 1101a and 1101b may overlap each other. In an embodiment, the first-1 and first-2 electrodes 1101a and 1101b may have a same shape on a plane and may completely overlap each other.

The second-1 and second-2 electrodes 2101a and 2101b may overlap each other. In an embodiment, the second-1 and second-2 electrodes 2101a and 2101b may have a same shape on a plane and may completely overlap each other.

The disclosure is not limited thereto, the first-1 and first-2 electrodes 1101a and 1101b may partially overlap each other, and the second-1 and second-2 electrodes 2101a and 2101b may partially overlap each other. However, in the present specification, for convenience of description, an embodiment of a case where the first-1 and first-2 electrodes 1101a and 1101b completely overlap each other and the second-1 and second-2 electrodes 2101a and 2101b completely overlap each other is shown and described.

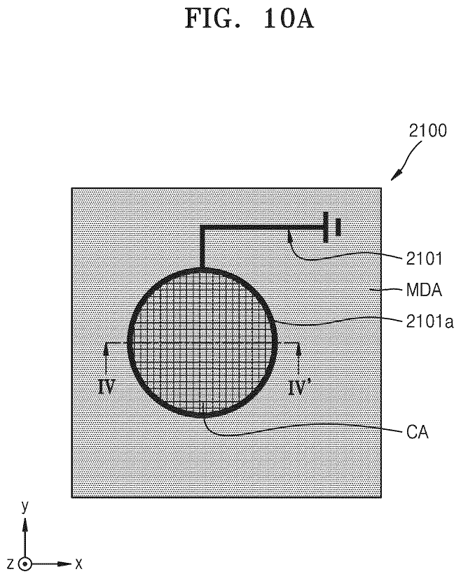

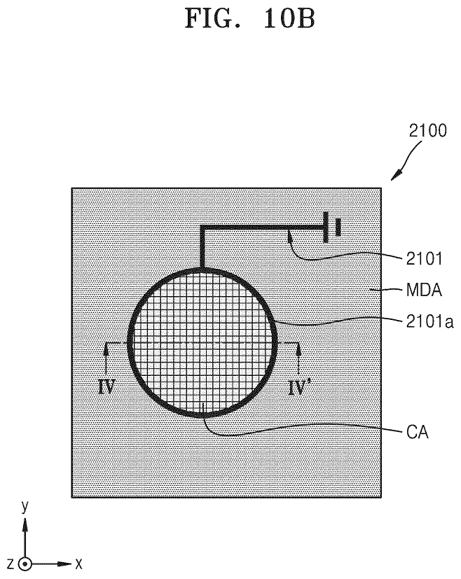

FIGS. 10A and 10B are schematic plan views of a portion of a display apparatus according to another embodiment.

FIGS. 10A and 10B are schematic plan views of a portion of a display apparatus according to the embodiment shown in FIG. 9.

Hereinafter, description is provided based on the second-1 electrode 2101a, but features described below may be equally applied to the first-1 electrode 1101a (FIG. 9), the first-2 electrode 1101b (FIG. 9), and the second-2 electrode 2101b (FIG. 9).

Referring to FIG. 10A, the second substrate 2100 may include the component region CA and the main display region MDA surrounding at least a portion of the component region CA.

The second-1 electrode 2101a may be arranged to surround the component region CA. For example, the second-1 electrode 2101a may have a substantially circular shape and surround the component region CA.

The second-1 electrode 2101a may include a mesh shape. For example, the second-1 electrode 2101a may include a mesh shape in a portion corresponding to the component region CA. However, the disclosure is not necessarily limited thereto, and the portion of the second-1 electrode 2101a, which corresponds to the component region CA, may include various shapes such as a stripe in a +x direction and a stripe in a ty direction or may be completely filled.

The second-1 electrode 2101a may be grounded. Because the second substrate 2100 may include an insulating material, the second-1 electrode 2101a may extend to an arbitrary region within the second substrate 2100 and be grounded. FIG. 10A illustrates that the second-1 electrode 2101a is grounded, but in another embodiment, the second-2 electrode 2101b (FIG. 9) may be grounded.

FIG. 10A illustrates that the component region CA has a circular shape and the second-1 electrode 2101a has a circular shape surrounding the component region CA, but the disclosure is not limited thereto. In another embodiment, the shape of the component region CA may be variously transformed into a polygon, a star shape, or a diamond shape, and the second-1 electrode 2101a may surround a portion of the component region CA.

Although not shown in FIGS. 10A and 10B, the second-2 electrode 2101b (FIG. 9), the first substrate 1100 (FIG. 9), and the first-1 and first-2 electrodes 1101a and 1101b (FIG. 9) may be arranged in a −z direction of the second substrate 2100.

The second-2 electrode 2101b (FIG. 9) may have a shape same as that of the second-1 electrode 2101a. Therefore, in a plan view, the second-2 electrode 2101b (FIG. 9) may be covered by the second-1 electrode 2101a and thus may not be visible. The disclosure is not limited thereto, and in another embodiment, the second-2 electrode 2101b (FIG. 9) and the second-1 electrode 2101a may partially overlap each other.

Each of the first-1 and first-2 electrodes 1101a and 1101b (FIG. 9) may have a shape same as that of the second-1 electrode 2101a. Therefore, in a plan view, the first-1 and first-2 electrodes 1101a and 1101b (FIG. 9) may be covered by the second-1 electrode 2101a and thus may not be visible. The disclosure is not limited thereto, and in another embodiment, and in another embodiment, the first-1 and first-2 electrodes 1101a and 1101b (FIG. 9) and the second-1 electrode 2101a may partially overlap each other.

Referring to FIG. 10B, a voltage may be applied to a non-grounded portion (for example, the second-2 electrode 2101b (FIG. 9)) of the second electrode 2101. In this case, a potential difference may occur between the second-1 electrode 2101a and the second-2 electrode 2101b (FIG. 9), and a portion of the second substrate 2100, which is arranged therebetween, may be exposed to an electric field.

Because the second substrate 2100 may include an electrochromic material, the transmittance of the second substrate 2100 may change when the second substrate 2100 is exposed to an electric field. For example, when the second substrate 2100 is exposed to an electric field, the transmittance of the second substrate 2100 may increase. An electric field may be formed in a region (or the component region CA) between the second-1 electrode 2101a and the second-2 electrode 2101b (FIG. 9) due to a potential difference therebetween. A portion of the second substrate 2100, which corresponds to the component region CA, may be exposed to an electric field, and thus, the transmittance of the second substrate 2100 may increase.

A process of forming an electric field between the first-1 and first-2 electrodes 1101a and 1101b (FIG. 9) and changing the transmittance of the first substrate 1100 (FIG. 9) may be similar to the relationship between the second-1 electrode 2101a, the second-2 electrode 2101b (FIG. 9), and the second substrate 2100.

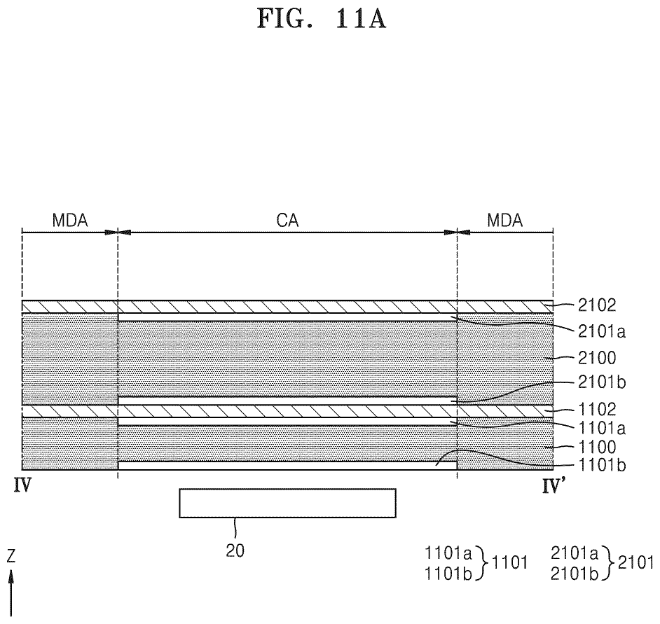

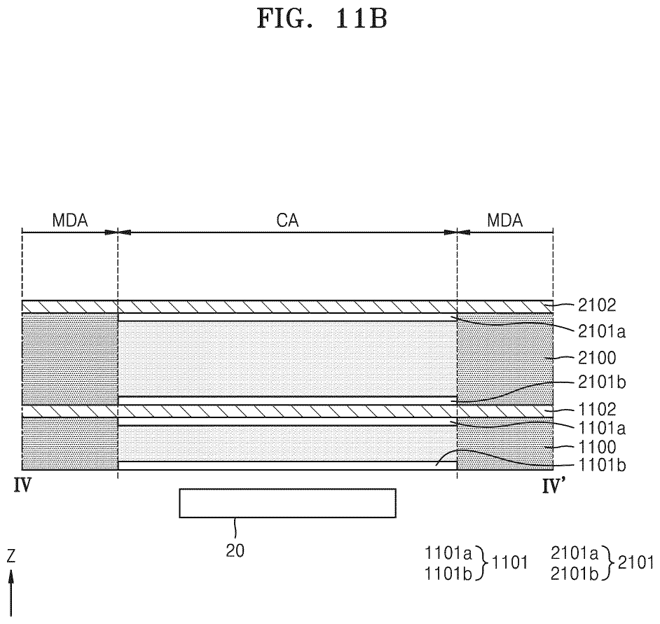

FIGS. 11A and 11B are schematic cross-sectional view of a portion of a display apparatus according to another embodiment.

FIG. 11A may be a cross-sectional view of one of various examples of the embodiment shown in FIG. 10A taken along line IV-IV′.

FIG. 11B may be a cross-sectional view of one of various examples of the embodiment shown in FIG. 10B taken along line IV-IV′.

Referring to FIG. 11A, the second electrode 2101 may include the second-1 electrode 2101a and the second-2 electrode 2101b. A first electrode 1101 may include the first-1 electrode 1101a and the first-2 electrode 1101b.

Planar shapes of the first-1 to second-2 electrodes 1101a, 1101b, 2101a, and 2101b may be similar to those described with reference to FIGS. 10A and 10B.

One of the first electrode 1101 and one of the second electrode 2101 may be grounded. For example, the first-1 electrode 1101a and the second-2 electrode 2101b may be grounded. In another embodiment, the first-2 electrode 1101b and the second-1 electrode 2101a may be grounded.

FIG. 11A illustrates that the first-1 to second-2 electrodes 1101a, 1101b, 2101a, and 2101b completely overlap each other, but the disclosure is not limited thereto. In another embodiment, the first-1 to second-2 electrodes 1101a, 1101b, 2101a, and 2101b may partially overlap each other.

The first-1 electrode 1101a may be arranged in a groove formed in an upper surface of the first substrate 1100. In other words, an upper surface of the first-1 electrode 1101a may be coplanar with the upper surface of the first substrate 1100.

The first-2 electrode 1101b may be arranged in a groove formed in a lower surface of the first substrate 1100. Alternatively, after the first-2 electrode 1101b is patterned, the first substrate 1100 may be disposed on the first-2 electrode 1101b. In other words, a lower surface of the first-2 electrode 1101b may be coplanar with the lower surface of the first substrate 1100.

FIG. 11A illustrates that the first-1 electrode 1101a is disposed on the upper surface of the first substrate 1100 and the first-2 electrode 1101b is disposed on the lower surface of the first substrate 1100, but the disclosure is not limited thereto. In another embodiment, one of the first-1 electrode 1101a and the first-2 electrode 1101b may be inserted into the first substrate 1100.

The second-1 electrode 2101a may be arranged in a groove formed in an upper surface of the second substrate 2100. In other words, an upper surface of the second-1 electrode 2101a may be coplanar with the upper surface of the second substrate 2100.

The second-2 electrode 2101b may be arranged in a groove formed in a lower surface of the second substrate 2100. Alternatively, after the second-2 electrode 2101b is patterned on the first barrier layer 1102, the second substrate 2100 may be disposed on the second-2 electrode 2101b. In other words, a lower surface of the second-2 electrode 2101b may be coplanar with the lower surface of the second substrate 2100.

FIG. 11A illustrates that the second-1 electrode 2101a is disposed on the upper surface of the second substrate 2100 and the second-2 electrode 2101b is disposed on the lower surface of the second substrate 2100, but the disclosure is not limited thereto. In another embodiment, one of the second-1 electrode 2101a and the second-2 electrode 2101b may be inserted into the second substrate 2100.

Referring to FIG. 11B, a voltage may be applied to a non-grounded electrode (for example, the first-2 electrode 1101b) of the first electrode 1101. In this case, a potential difference may occur between the first-1 electrode 1101a and the first-2 electrode 1101b, and a portion of the first substrate 1100, which is arranged therebetween, may be exposed to an electric field.

Because the first substrate 1100 may include an electrochromic material, the transmittance of the first substrate 1100 may change when the first substrate 1100 is exposed to an electric field. For example, when the first substrate 1100 is exposed to an electric field, the transmittance of the first substrate 1100 may increase. An electric field may be formed in the component region CA due to a potential difference between the first-1 electrode 1101a and the first-2 electrode 1101b. A portion of the first substrate 1100, which corresponds to the component region CA, may be exposed to an electric field, and thus, the transmittance of the first substrate 1100 may increase.

A voltage may be applied to a non-grounded portion (for example, the second-1 electrode 2101a) of the second electrode 2101. In this case, a potential difference may occur between the second-1 electrode 2101a and the second-2 electrode 2101b, and a portion of the second substrate 2100, which is arranged therebetween, may be exposed to an electric field.

Because the second substrate 2100 may include an electrochromic material, the transmittance of the second substrate 2100 may change when the second substrate 2100 is exposed to an electric field. For example, when the second substrate 2100 is exposed to an electric field, the transmittance of the second substrate 2100 may increase. An electric field may be formed in the component region CA due to a potential difference between the second-1 electrode 2101a and the second-2 electrode 2101b. A portion of the second substrate 2100, which corresponds to the component region CA, may be exposed to an electric field, and thus, the transmittance of the second substrate 2100 may increase.

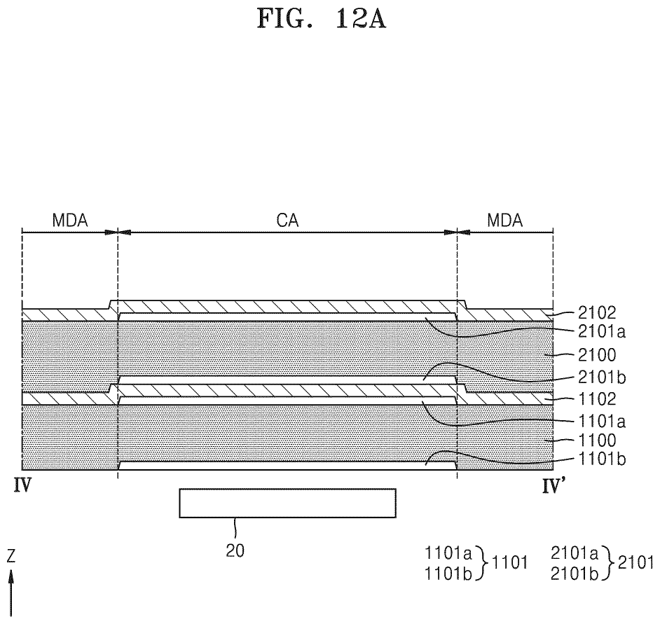

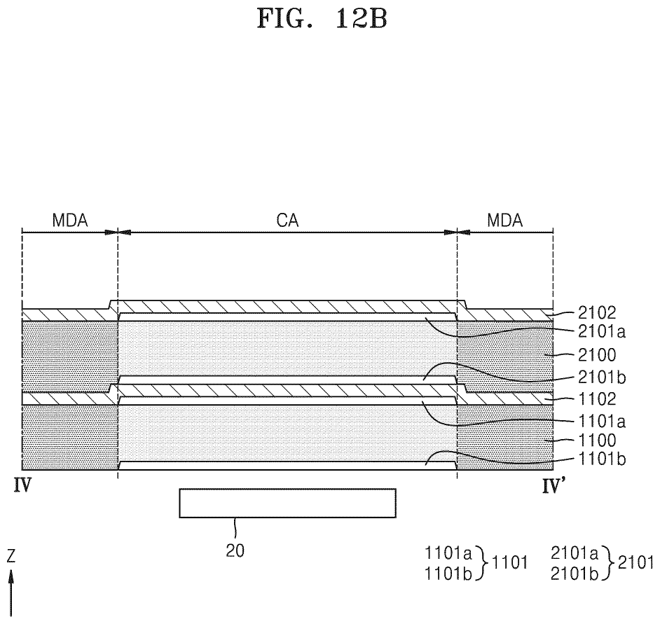

FIGS. 12A and 12B are schematic cross-sectional view of a portion of a display apparatus according to another embodiment.

FIG. 12A may be a cross-sectional view of one of various examples of the embodiment shown in FIG. 10A taken along line IV-IV′.

FIG. 12B may be a cross-sectional view of one of various examples of the embodiment shown in FIG. 10B taken along line IV-IV′.

Referring to FIG. 12A, the first-1 electrode 1101a may be disposed on the first substrate 1100. In this case, the first-1 electrode 1101a may be patterned on the first substrate 1100. In other words, a lower surface of the first-1 electrode 1101a may be coplanar with an upper surface of the first substrate 1100.

The second-1 electrode 2101a may be disposed on the second substrate 2100. In this case, the second-1 electrode 2101a may be patterned on the second substrate 2100. In other words, a lower surface of the second-1 electrode 2101a may be coplanar with an upper surface of the second substrate 2100.

In addition, features related to the embodiments shown in FIGS. 12A and 12B are the same as those described with reference to FIGS. 11A and 11B.

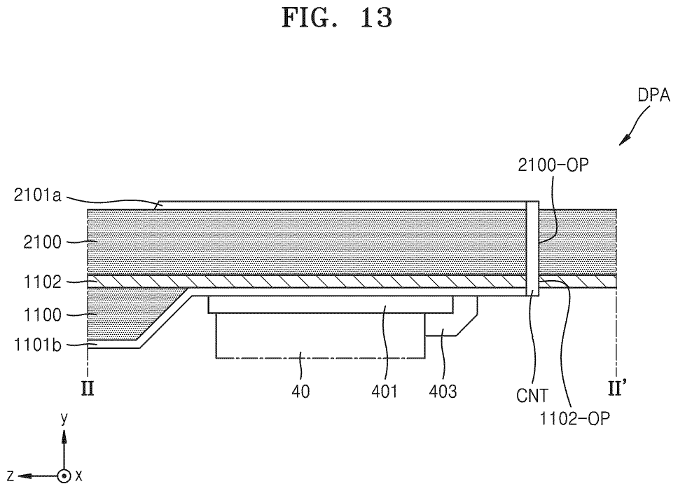

FIG. 13 is a schematic cross-sectional view of a portion of a display apparatus according to another embodiment.

FIG. 13 is a cross-sectional view of one of various examples of the embodiment shown in FIG. 3 taken along line II-II′.

Hereinafter, among features of an embodiment shown in FIG. 13, differences from the embodiment shown in FIG. 8 are mainly described.

Referring to FIG. 13, the second-1 electrode 2101a may be disposed on the second substrate 2100. The first-2 electrode 1101b may be disposed below the first substrate 1100.

The connection line CNT may be arranged in the opening 2100-OP of the second substrate 2100 and the opening 1102-OP of the first barrier layer 1102. The connection line CNT may be connected to the second-1 electrode 2101a and the first-2 electrode 1101b. In some embodiments, the connection line CNT may be a portion of the second-1 electrode 2101a or the first-2 electrode 1101b extending from the second-1 electrode 2101a or the first-2 electrode 1101b, respectively.

The second-1 electrode 2101a and the first-2 electrode 1101b may be electrically connected to each other via the connection line CNT. A same voltage may be applied to the second-1 electrode 2101a and the first-2 electrode 1101b.

The terminal portion 40 may be arranged to be adjacent to the first-2 electrode 1101b. The bump layer 401 may be arranged between the terminal portion 40 and the first-2 electrode 1101b.

The conductive ink layer 403 may protrude from a side surface of the terminal portion 40 and may be connected to the bottom of the first-2 electrode 1101b.

The conductive ink layer 403 may electrically connect the terminal portion 40 with the first-2 electrode 1101b. An electrical signal generated from the terminal portion 40 may be transferred to the first-2 electrode 1101b, the connection line CNT, and the second-1 electrode 2101a via the conductive ink layer 403. In other words, the first-2 electrode 1101b and the second-1 electrode 2101a may receive a voltage from the terminal portion 40 via the conductive ink layer 403.

In this case, because a voltage is applied to the second-1 electrode 2101a and the first-2 electrode 1101b, it may be understood that the second-2 electrode 2101b (FIG. 11B) and the first-1 electrode 1101a (FIG. 11B) are grounded.

FIG. 13 illustrates that the terminal portion 40, the bump layer 401, and the conductive ink layer 403 are arranged under the first-2 electrode 1101b, but the disclosure is not limited thereto. In another embodiment, the terminal portion 40, the bump layer 401, and the conductive ink layer 403 may be disposed on the second-1 electrode 2101a.

The embodiments shown in FIGS. 6A and 6B may be defined as a first embodiment, the embodiments shown in FIGS. 7A and 7B may be defined as a second embodiment, the embodiments shown in FIGS. 11A and 11B may be defined as a third embodiment, and the embodiments shown in FIGS. 12A and 12B may be defined as a fourth embodiment.

Both ends of a circuit to which a voltage is applied to form an electric field are implemented via first and second portions (for example, the first and second portions 2101a-1 and 2101a-2 of the second-1 electrode 2101a (FIG. 6)) of an electrode, which are arranged on a same plane, in the first and second embodiments. In the third and fourth embodiments, implementation is made via second electrodes (for example, the first-1 electrode 1101a and the first-2 electrode 1101b (FIG. 11A) arranged on different planes.

Because the electrode including a plurality of portions in the same plane is formed in the first and second embodiments, the electrode may be formed via a single mask.

Because a plurality of electrodes are formed on different planes in the third and fourth embodiments, the electrodes may be formed via a plurality of masks.

In the first and second embodiments, the electrode including the plurality of portions on a same plane is arranged, and thus, there may be a difference in magnitude between an electric field formed on the same plane and an electric field formed on a different plane in a +z direction. For example, in the first embodiment, an electric field may decrease away from a same plane on which the first and second portions 2101a-1 and 2101a-2 (FIG. 6B) of the second-1 electrode 2101a (FIG. 6B) are arranged. In this case, a driving voltage required in the first and second embodiments may be about 3 V or more to achieve a transmittance (for example, a transmittance of about 80% or more) greater than or equal to a target transmittance.

Because a plurality of electrodes are arranged in different planes in the third and fourth embodiments, a constant electric field may be formed in a portion of a substrate, which is arranged between the electrodes. For example, in the third embodiment, a constant electric field may be formed between the second-1 and second-2 electrodes 2101a and 2101b (FIG. 11B) in a +z direction. In this case, a driving voltage required in the third and fourth embodiments may be about 0.5 V to about 3 V achieve a transmittance (for example, a transmittance of about 80% or more) greater than or equal to a target transmittance.

Therefore, as compared to the first and second embodiments, in the third and fourth embodiments, electrochromic efficiency may be high, and a driving voltage may be low, which may be advantageous in use. As compared to the third and fourth embodiments, the first and second embodiments may have advantages in manufacturing processes because the number of masks required for forming an electrode is small.

According to an embodiment, a display apparatus having improved transmittance of a component region by applying a voltage to the component region of the display apparatus including a substrate including an electrochromic material may be implemented. However, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope as defined by the following claims.

What is claimed is:

1. A display apparatus comprising:
a first substrate comprising a component region and a main display region surrounding at least a portion of the component region;
a second substrate disposed on the first substrate and comprising a component region and a main display region surrounding at least a portion of the component region;
a first-1 electrode disposed on one surface of the first substrate; and
a second-1 electrode disposed on one surface of the second substrate,
wherein each of the first substrate and the second substrate comprises an electrochromic material.

2. The display apparatus of claim 1, wherein, in a plan view, at least one of the first-1 electrode and the second-1 electrode surrounds at least a portion of the component region.

3. The display apparatus of claim 1, wherein at least a portion of the first-1 electrode and at least a portion of the second-1 electrode overlap each other.

4. The display apparatus of claim 1, further comprising a first-2 electrode disposed on a surface opposite to the one surface of the first substrate, on which the first-1 electrode is disposed.

5. The display apparatus of claim 1, further comprising a second-2 electrode disposed on a surface opposite to the one surface of the second substrate, on which the second-1 electrode is disposed.

6. The display apparatus of claim 1, wherein each of the first substrate and the second substrate comprises a peripheral region surrounding the main display region, and
a portion of the first-1 electrode and a portion of the second-1 electrode are each arranged in the peripheral region to bypass the main display region.

7. The display apparatus of claim 6, wherein the second substrate comprises an opening arranged in the peripheral region and penetrating the second substrate.

8. The display apparatus of claim 6, wherein the first-1 electrode and the second-1 electrode are connected to each other in a portion of the peripheral region.

9. The display apparatus of claim 1, wherein transmittance of each of the first substrate and the second substrate increases when a voltage is applied thereto.

10. The display apparatus of claim 1, further comprising a barrier layer arranged between the first substrate and the second substrate.

11. A display apparatus comprising:
a substrate comprising a first substrate, a second substrate, a component region, and a main display region surrounding at least a portion of the component region;
a first electrode disposed on one surface of the first substrate; and
a second electrode disposed on one surface of the second substrate,
wherein transparency of at least one of the first substrate and the second substrate varies according to a voltage applied to the first electrode or the second electrode.

12. The display apparatus of claim 11, wherein the first electrode is disposed on a lower surface of the first substrate.

13. The display apparatus of claim 11, wherein the first electrode or the second electrode is arranged between the first substrate and the second substrate.

14. The display apparatus of claim 11, wherein the second electrode is arranged between the second substrate and an inorganic layer on the substrate.

15. The display apparatus of claim 11, wherein the first electrode is inserted into the first substrate, or the second electrode is inserted into the second substrate.

16. The display apparatus of claim 11, wherein one surface of the first electrode is coplanar with the one surface of the first substrate, or one surface of the second electrode is coplanar with the one surface of the second substrate.

17. The display apparatus of claim 11, wherein at least a portion of the first electrode overlaps at least a portion of the second electrode.

18. The display apparatus of claim 11, wherein at least a portion of at least one of the first electrode and the second electrode overlaps the component region.

19. The display apparatus of claim 11, further comprising a barrier layer arranged between the first substrate and the second substrate, wherein at least one of the first electrode and the second electrode is arranged in the barrier layer.

20. The display apparatus of claim 11, further comprising a connection line arranged in a peripheral region arranged outside the main display region to bypass the main display region and connected with the first electrode or the second electrode.
